(19) United States
(12) Patent Application Publication
(10) Pub. No.: US 2024/0200699 A1
(43) Pub. Date: Jun. 20, 2024

(54) JOINT

(71) Applicant: FUJIKIN INCORPORATED, Osaka-shi (JP)

(72) Inventors: Yasumasa Yanagida, Osaka-shi (JP); Koji Hiramatsu, Osaka-shi (JP); Tomoya Kanzaki, Osaka-shi (JP); Tadayuki Yakushijin, Osaka-shi (JP); Yoshinori Shimomura, Osaka-shi (JP)

(73) Assignee: FUJIKIN INCORPORATED, Osaka-shi (JP)

(21) Appl. No.: 18/287,196

(22) PCT Filed: Apr. 12, 2022
(86) PCT No.: PCT/JP2022/017578

§ 371 Date: Oct. 17, 2023

(30) Foreign Application Priority Data
Apr. 19, 2021 (JP) 2021-070152

(51) Int. Cl. F16L 19/065; F16L 19/025

(52) U.S. Cl. CPC F16L 19/0653; F16L 19/025

(57) ABSTRACT

An object is to provide a joint in which a tapered portion of a body to which surface treatment has been applied is not seized when a pipe is attached. The joint includes a body having a tapered portion on an inner peripheral surface of at least one end portion, a threaded portion on an outer peripheral surface of the at least one end portion, and a flow path therein; a ring having a tapered outer peripheral surface in sliding contact with the tapered portion of the body; and a nut pushing the tapered outer peripheral surface of the ring against the tapered surface of the body by being screwed with a parallel threaded portion of the threaded portion of the body to which a pipe is connected and, in which surface treatment for preventing adsorption of liquid is applied to a surface of the body.

### TECHNICAL FIELD

The present invention relates to a joint for coupling pipes to each other and, more specifically, a joint having a body to which surface treatment, such as water repellent treatment, needs to be applied.

### BACKGROUND ART

There is a proposed joint for connecting metal pipes to each other includes a cylindrical body having male threads formed at both ends thereof, rings that have tapered outer peripheral surfaces in sliding contact with tapered portions on inner surfaces at both ends of the body and bites into the pipes by the diameters of the tip portions reducing along the tapering, and nuts that push the tapered surfaces of the rings against the tapered surfaces of the body by being screwed with the male threads of the body. Such joints are widely used in general industrial fields.

In this conventional joint, in order to firmly fix the pipes and prevent the fluid circulating inside from leaking to the outside, each of the rings includes a front ring in sliding contact with the tapered surface of the body and a backup ring that directly receives a pressing force from the nut (see, for example, Patent Literature 1 and Patent Literature 2).

### CITATION LIST

### Patent Literature

Patent Literature 1: JP2015-197137A
Patent Literature 2: JP2004-044633A

### SUMMARY OF INVENTION

### Technical Problem

Such joints may need to be protected from the fluid used and the environment and the atmosphere in which the pipes are deployed. For example, surface modification treatment, film deposition treatment (for example, chemical vapor deposition (CVD)), and the like for preventing adsorption of water and sulfur and improving corrosion resistance are performed.

When surface treatment, particularly chemical vapor deposition treatment is applied to the surface of the joint, depending on the vapor deposition component used (for example, amorphous silica or the like), the tapered portions of the body are seized as illustrated in FIG. 6 when the nuts are tightened to strongly bring the rings into sliding contact with the tapered surfaces of the body. There is a problem in that seizure of the body causes the fluid circulating through the pipe to leak to the outside. In addition, it is also conceivable to mask the tapered portions of the body before surface treatment, but there is a problem in that a dedicated jig needs to be attached, the work becomes complicated, and the cost increases.

The present invention addresses such problems with an object of providing a joint in which the tapered portions of the body to which surface treatment has been applied are not seized when pipes are attached.

### Solution to Problem

A joint according to the present invention for solving the problem described above includes a body having a tapered portion on an inner peripheral surface of at least one end portion, a threaded portion on an outer peripheral surface of the at least one end portion, and a flow path therein; a ring having a tapered outer peripheral surface in sliding contact with the tapered portion of the body; and a nut that pushes the tapered outer peripheral surface of the ring against a tapered surface of the body by being screwed with the threaded portion of the body, in which surface treatment for preventing adsorption of liquid is applied to a surface of the body, and gold-plating is applied to a surface of the ring.

The joint according to the present invention successfully suppresses the tapered surface of the body to which surface treatment, such as chemical vapor deposition, has been applied from being seized by the ring in sliding contact with the tapered surface of the body by using gold-plating on the surface of the ring found by diligent study of the present inventors.

In this case, the surface treatment may be a chemical vapor deposition method. At this time, for example, amorphous silica or the like can be used as the vapor deposition component.

In this case, the ring may include a front ring in sliding contact with the tapered surface of the body and a backup ring disposed between the front ring and an annular bottom surface of the nut.

### Advantageous Effects of Invention

In the joint according to the present invention, it is possible to effectively suppress seizure of the tapered portion of the body to which water repellent treatment has been entirely applied caused during attachment of pipes by using surface treatment, such as a chemical vapor deposition method.

### BRIEF DESCRIPTION OF DRAWINGS

FIG. 1 is a front sectional view illustrating a joint according to a first embodiment of the present invention, in which (a) illustrates the state in which pipes are not yet coupled to each other and (b) illustrates the state in which the tips of rings have bit into the pipes after the pipes are coupled to each other.

FIG. 2 is a front sectional view illustrating a joint according to a second embodiment of the present invention and illustrates the state in which the pipes are not yet coupled to each other.

FIG. 3 is a front sectional view illustrating a joint according to a third embodiment of the present invention and illustrates the state in which the pipes are not yet coupled to each other.

FIG. 4 is a front sectional view illustrating a joint according to a fourth embodiment of the present invention and illustrates the state in which the pipes are not yet coupled to each other.

FIG. 5 is an enlarged photograph of a tapered portion of a body with a nut loosened after the pipes are coupled to each other by a joint according to the present invention.

FIG. 6 is an enlarged photograph of a tapered portion of a body with a nut loosened after pipes are coupled to each other by a joint to which surface treatment is applied and having the nuts to which gold-plating is not applied, in which (a) is an enlarged photograph of the entire tapered portion, (b) is an enlarged photograph of portion b in (a), and (c) is an enlarged photograph of portion c in (a).

### DESCRIPTION OF EMBODIMENTS

Preferable embodiments of a joint according to the present invention will be described below with reference to the drawings. Unless otherwise specified, the shapes of components described in this example, the relative disposition thereof, and the like do not limit the scope of the present invention and are only explanatory examples. In addition, for the sake of convenience, the directions of members and the like are sometimes referred to as up, down, left, and right in accordance with the direction in the drawing, but these do not limit the scope of the present invention.

### First Embodiment

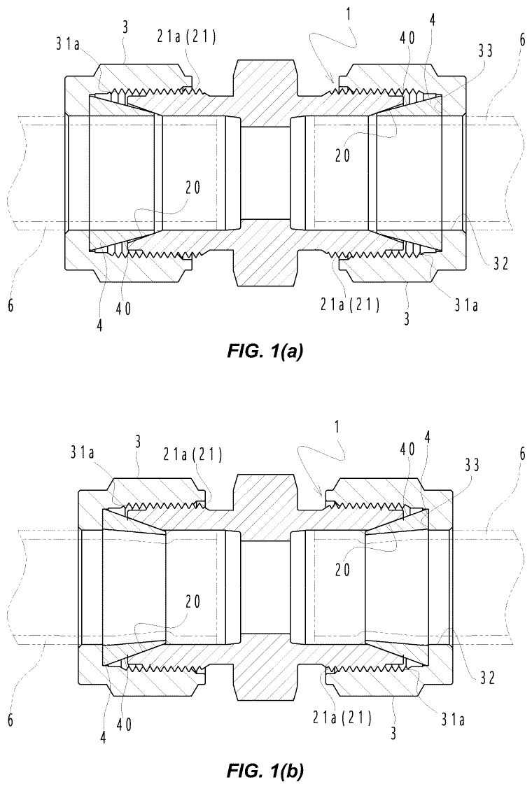

FIG. 1 illustrates a joint according to a first embodiment of the present invention. FIG. 1 is a front sectional view illustrating a joint 1 according to the present invention, FIG. 1(a) illustrates the state in which the pipes are not yet coupled to each other, and (b) illustrates the state in which the tips of the rings have bit into the pipes after the pipes are coupled to each other. This joint 1 includes a cylindrical body 2 having threaded portions 21 on the outer peripheral surfaces at both ends and a tapered portion 20 on an inner peripheral surface of at least one end portion, rings 4 having tapered outer peripheral surfaces 40 in sliding contact with the tapered portions 20 of the body 2, and nuts 3 that push the tapered outer peripheral surfaces 40 of the ring 4 against the tapered portion 20 of the body 2 by being screwed with parallel threaded portions 21a, which are parts of the threaded portions 21 of the body 2 to which pipes 6 are connected.

The body 2 is a cylindrical body into which end portions of the pipes 6 are inserted to form the flow path 22 through which fluid can circulate and includes a holding portion 23, for example, having hexagonal shape, for fixing the body 2 with a tool or the like in the central portion and the parallel threaded portions 21a and 21a at both ends with which the nuts 3 are screwed.

In addition, surface treatment for preventing adsorption of liquid is applied to the surface of the body as water repellent treatment. Film deposition is performed as the surface treatment. This film deposition method is not particularly limited but can be, for example, chemical vapor deposition such as a chemical vapor deposition (CVD) method. Alternatively, a physical vapor deposition (PVD) method can also be employed.

The CVD method is a film deposition method that uses chemical reactions that make full use of a technology for transporting raw materials and reaction products in a viscous flow area, and, for example, amorphous silica and the like can be used as vapor deposition component for film deposition. In addition, chemical reactions by CVD are induced by heat, light, plasma, and the like, but the method is not particularly limited in the present invention.

The material of the body 2 is not particularly limited as long as the material is a metal, but the material is, for example, stainless steel (such as SUS316).

In the embodiment, the body 2 has the threaded portions 21 at both ends. As described above, the threaded portions 21 are the parallel threaded portions 21a with which parallel threaded portions 31 formed on an inner peripheral surfaces of the nuts 3 are screwed.

Each of the nuts 3 has an annular bottom portion 33 on the bottom surface thereof and has an insertion opening 32 through which the pipe 6 passes. The annular bottom portion 33 pushes the ring 4 against the body 2 side by screwing the parallel threaded portion 31 formed on the inner peripheral surface of the nut 3 with the parallel threaded portion 21a of the body 2.

The ring 4 is an annular member that has the tapered outer peripheral surface 40 with an inclination angle θ2 (for example, 30°) that is smaller than an inclination angle θ1 (for example, 40°) of the tapered portion 20 of the body 2 and has substantially the same inner diameter as the insertion opening 32 of the nut 3 described above.

In addition, gold-plating is applied to at least the tapered outer peripheral surface 40 of the ring 4. The thickness of the gold plating is not particularly limited, but, in the embodiment, the thickness is 0.01 μm to 0.8 μm, and preferably 0.1 μm to 0.5 μm. In addition, there are two types of gold plating: hard gold plating and pure gold plating (soft gold plating), and both types are acceptable, but hard gold plating having high film hardness is used in the embodiment.

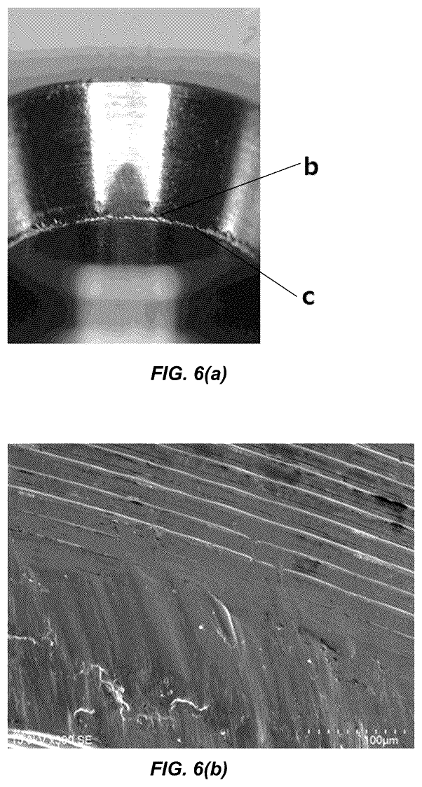

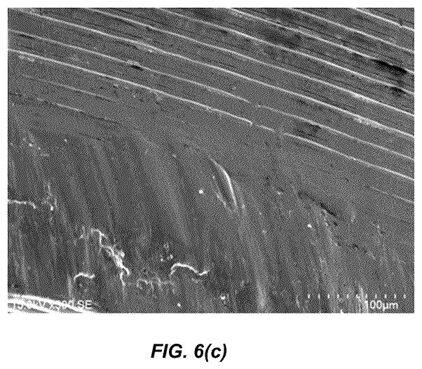

FIG. 5 illustrates a photograph of the tapered portion 20 of the body 2 observed after the pipe is fixed by using the ring 4 to which gold-plating has been applied and then the nut 3 is loosened. It can be seen that seizure does not occur as compared with the photograph of the tapered portion 20 to which gold-plating has not been applied in FIG. 6(a).

### Second Embodiment

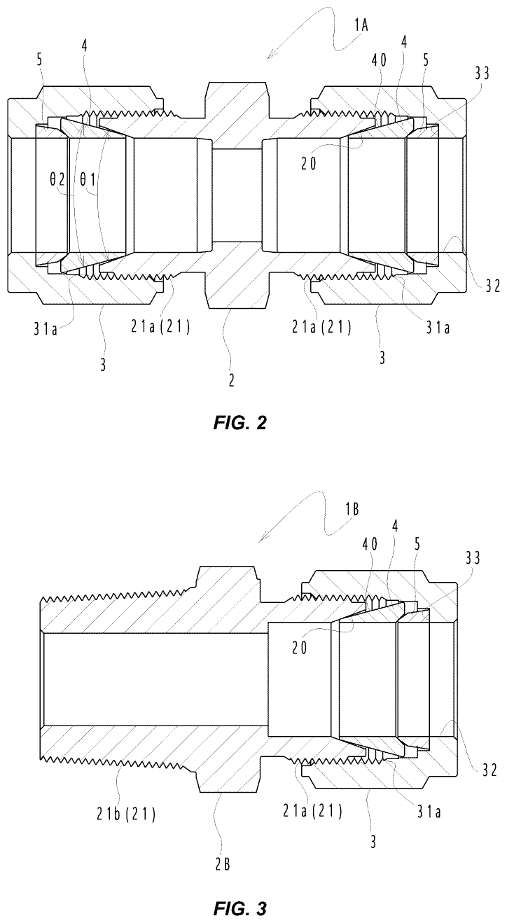

FIG. 2 illustrates a joint according to a second embodiment of the present invention. In this joint 1A, the rings 4 according to the first embodiment are front rings 4, and backup rings 5 are disposed between the front rings 4 and the annular bottom portions 33 of the nuts.

Each of the front rings 4 has the tapered outer peripheral surface 40 as the outer peripheral surface as in the first embodiment and also has a tapered surface on an inner peripheral surface close to the nut 3.

In addition, a tapered surface is formed on an outer peripheral surface of the backup ring 5 close to the front ring 4. The front ring 4 is pushed against the tapered outer peripheral surface 40 of the body 2 while the backup ring 5 is pushed directly by the parallel threaded portion 31 formed on the inner peripheral surface of the nut 3 being screwed with the parallel threaded portion 21a of the body 2. At this time, the tip portion of the front ring 4 bites into the pipe 6, and the tip portion of the backup ring 5 also bites into the pipe 6 as the tip portion of the front ring 4. As the biting amount increases, the force for holding the pipe increases, the tightening resistance increases, and the tightening torque increases.

### Other Embodiments

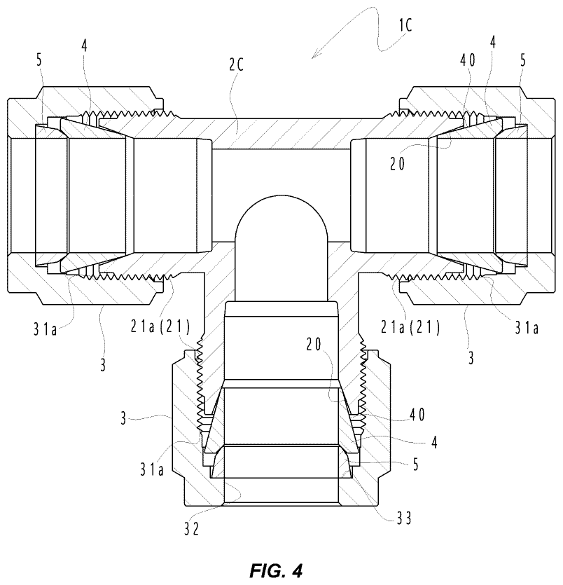

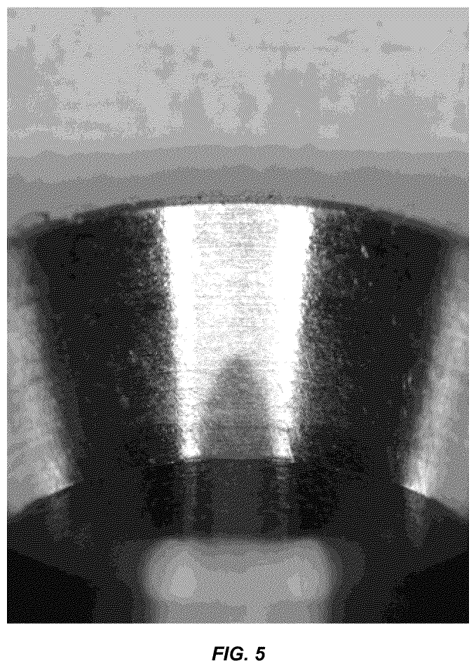

FIGS. 3 and 4 illustrate joints according to other embodiments of the present invention.

In a joint 1B illustrated in FIG. 3, one end of a body 2B has a shape similar to that in the second embodiment and is screwed with the nut 3, and the threaded portion 21 at the other end is a tapered threaded portion 21b directly screwed with a piping block or the like. A union male threaded portion may be formed instead of this tapered threaded portion 21b.

In addition, the body 2B has a straight pipe shape as an example but may have an elbow shape or a 45-degree elbow shape.

A body 2C of a joint 1C illustrated in FIG. 4 is T-shaped and has three end portions. Alternatively, the body 2C may be cross-shaped and have four end portions.

In addition, each of the end portions may be the tapered threaded portion 21b as in the joint 1B or may be a union male portion.

### INDUSTRIAL APPLICABILITY

The joint according to the present invention can be preferably used as a pipe joint for fluid for which surface treatment, such as water repellent treatment, is required, and the joint can be preferably used as a joint for connecting pipes for, for example, petroleum and petrochemical plants, analytical instruments, and the like.

### REFERENCE SIGNS LIST

1: joint
2: body
20: tapered portion
21: threaded portion
3: nut
4: ring (front ring)
40: tapered outer peripheral surface
5: back ring
6: pipe

1. A joint comprising:
a body having a tapered portion on an inner peripheral surface of at least one end portion, a threaded portion on an outer peripheral surface of the at least one end portion, and a flow path therein;
a ring fitted onto a pipe, the ring having a tapered outer peripheral surface in sliding contact with the tapered portion of the body; and
a nut having an insertion hole through which the pipe passes, the nut pushing the tapered outer peripheral surface of the ring against the tapered surface of the body by being screwed with the threaded portion of the body,
wherein surface treatment for preventing adsorption of liquid is applied to a surface of the body, and gold-plating is applied to a surface of the ring.

2. The joint according to claim 1,
wherein the surface treatment is a chemical vapor deposition method.

3. The joint according to claim 1,
wherein the ring includes a front ring in sliding contact with the tapered surface of the body and a backup ring disposed between the front ring and an annular bottom surface of the nut.

4. The joint according to claim 2,
wherein the ring includes a front ring in sliding contact with the tapered surface of the body and a backup ring disposed between the front ring and an annular bottom surface of the nut.
